(19) United States
(12) Patent Application Publication
(10) Pub. No.: US 2014/0083453 A1
(43) Pub. Date: Mar. 27, 2014

(54) METHOD FOR IN SITU CLEANING OF MOCVD REACTION CHAMBER

(71) Applicant: Advanced Micro-Fabrication Equipment Inc, Shanghai, Shanghai (CN)

(72) Inventors: Gerald Zheyao Yin, Shanghai (CN); Zhiyou Du, Shanghai (CN); Shuang Meng, Shanghai (CN); Yang Wang, Shanghai (CN); Ying Zhang, Shanghai (CN); Songlin Xu, Shanghai (CN); Ban Zhu, Shanghai (CN); Haruhisa Takiguchi, Shanghai (CN)

(73) Assignee: Advanced Micro-Fabrication Equipment Inc, Shanghai, Shanghai (CN)

(21) Appl. No.: 14/032,138

(22) Filed: Sep. 19, 2013

(30) Foreign Application Priority Data
Sep. 26, 2012 (CN) 201210364958.X

(51) Int. Cl. C23C 16/44

(52) U.S. Cl. CPC C23C 16/4405
USPC 134/1.1

(57) ABSTRACT

A method for in situ cleaning of a Metal-Organic Chemical Vapor Deposition reaction chamber is provided in embodiments of the present invention. The method includes: introducing a first cleaning gas into the reaction chamber, converting the first cleaning gas into first plasma inside the reaction chamber to completely remove a carbonaceous organic substance inside the reaction chamber, wherein the first cleaning gas includes a first oxygen-containing gas; and introducing a second cleaning gas into the reaction chamber, and converting the second cleaning gas into second plasma inside the reaction chamber to completely remove a metallic oxide inside the reaction chamber, wherein the second cleaning gas includes a first halogen-containing gas.

### CROSS REFERENCE TO RELATED APPLICATION

This application claims the benefit of priority to Chinese Patent Application No.201210364958.X, entitled “METHOD FOR IN SITU CLEANING OF MOCVD REACTION CHAMBER”, filed on Sep. 26, 2012 with State Intellectual Property Office of PRC, which is incorporated herein by reference in its entirety.

### FIELD OF THE INVENTION

The present invention relates to semiconductor manufacture, and in particular, to a method for in situ cleaning of a Metal-Organic Chemical Vapor Deposition (MOCVD) reaction chamber.

### BACKGROUND OF THE INVENTION

At present, the MOCVD (Metal-Organic Chemical Vapor Deposition) technology is widely used to prepare compounds of Group III elements and Group V elements (such as GaN, InN, AN, InGaN, AlGaN and GaP). In the state of the art, in an MOCVD reaction chamber for the preparation of the compound of the Group III element(s) and the Group V element(s), there is a main problem that extra solid by-product deposits (such as carbonaceous organic substances or metal and its compound(s)) may be generated in the reaction chamber after each reaction step. These deposits are deposited inside the reaction chamber (for example, at a shower head, a susceptor and an inner wall), resulting in process drift and degraded performance. Moreover, impurities such as particulates are prone to be formed on a surface of a substrate during the preparation of the compound of the Group III element(s) and the Group V element(s), and these impurities may affect subsequent processes. Therefore, the MOCVD reaction chamber needs to be cleaned when being used, to remove the deposits inside the reaction chamber and to improve the quality of the prepared compound of the Group III element(s) and the Group V element(s).

In the prior art, the deposits inside the MOCVD reaction chamber are generally removed manually. Specifically, the MOCVD reaction chamber is opened, and then the deposits at the shower head and so on are removed manually. However, for the manual removal, the productivity is low, the repeatability is poor, and the cleaning efficiency is not high. For this reason, some methods for in situ removal of the deposits inside the MOCVD reaction chamber are developed in the prior art. In these methods, the gas containing halide(s) (such as Cl₂, HCl and HBr) is introduced into the MOCVD reaction chamber to remove the deposits in situ. For this kind of cleaning method, the MOCVD reaction chamber does not need to be opened, the repeatability is good, the cleaning efficiency is high and the productivity is high.

However, on the surfaces with a relatively low temperature (for example, the surface of the shower head undergone water cooling, or the surface of the inner wall of the reaction chamber), precursors of metal organic compound are decomposed incompletely and form extra deposits. These extra deposits mainly contain relatively stable organic ligands or related polymers and metal and its compound(s). These relatively stable organic ligands or related polymers are mainly highly concentrated carbonaceous organic substances. In this case, this kind of in situ cleaning based on the simple halide(s) (such as Cl₂, HCl and HBr) has no effect on the removal of the deposits on the surfaces with the relatively low temperature.

### SUMMARY OF THE INVENTION

For the capability of removing deposits on surfaces with a relatively low temperature inside an MOCVD reaction chamber, the embodiments of the present invention provide a method for in situ cleaning of deposits inside the MOCVD reaction chamber. The method includes:

performing Step a, including:

introducing a first cleaning gas into the reaction chamber, and converting the first cleaning gas into a first plasma inside the reaction chamber; and/or,

converting the first cleaning gas into the first plasma outside the reaction chamber, and introducing the first plasma into the reaction chamber; and/or,

introducing the first cleaning gas into the reaction chamber, and maintaining a temperature inside the reaction chamber in a range of 200° C. to 500° C.; and

maintaining a pressure inside the reaction chamber in a first predetermined pressure range for a first time period to completely remove a carbonaceous organic substance inside the reaction chamber and convert a metal and its compound inside the reaction chamber into a metallic oxide; wherein the first cleaning gas includes a first oxygen-containing gas; and

performing Step b, including:

introducing a second cleaning gas into the reaction chamber, and converting the second cleaning gas into a second plasma inside the reaction chamber; and/or,

converting the second cleaning gas into the second plasma outside the reaction chamber, and introducing the second plasma into the reaction chamber; and/or,

introducing the second cleaning gas into the reaction chamber, and maintaining the temperature inside the reaction chamber in a range of 200° C. to 500° C.; and

maintaining the pressure inside the reaction chamber in a second predetermined pressure range for a second time period to completely remove the metallic oxide inside the reaction chamber; wherein the second cleaning gas includes a first halogen-containing gas.

preferably, the first cleaning gas further includes Ar; and/or, the second cleaning gas further includes Ar.

Preferably, the first cleaning gas further includes a second halogen-containing gas including one of HCl, BCl₃, Cl₂, a gas mixture of H₂/Cl₂, HBr or any combination thereof.

Preferably, in the first cleaning gas, the mole fraction of the first oxygen-containing gas is larger than the mole fraction of the second halogen-containing gas.

Preferably, the second cleaning gas further includes a second oxygen-containing gas including one of O₂, O₃, CO₂, H₂O₂, N₂O, CO or any combination thereof

Preferably, in the second cleaning gas, the mole fraction of the first halogen-containing gas is larger than the mole fraction of the second oxygen-containing gas.

Preferably, the first oxygen-containing gas includes one of O₂, O₃, CO₂, H₂O₂, N₂O or any combination thereof.

Preferably, the first halogen-containing gas includes one of HCl, BCl₃, a gas mixture of BCl/O₂, a gas mixture of H₂/Cl₂, Cl₂, HBr or any combination thereof

Preferably, the first time period is longer than 5 minutes and the second time period is longer than 3 minutes.

In the embodiments of the present invention, the carbonaceous organic substances inside the reaction chamber are removed by using the first cleaning gas including a first oxygen-containing gas and/or the plasma of the first cleaning gas, and the metal(s) and its compound(s) inside the reaction chamber are removed by using the second cleaning gas including the halogen-containing gas and/or the plasma of the second cleaning gas. The method for in situ cleaning of the MOCVD reaction chamber according to the embodiments of the present invention is capable of removing deposits containing relatively stable organic ligands or related polymers and metal and its compound(s), and therefore has a good cleaning effect for the deposits on the surfaces with a relatively low temperature inside the reaction chamber.

### BRIEF DESCRIPTION OF THE DRAWINGS

The drawings used in the description of the embodiments or the prior art will be described briefly as follows, so that the technical solutions according to the embodiments of the present invention or according to the prior art will become clearer. Like reference numerals refer to like components in the drawings. It is obvious that the drawings in the following description are only some embodiments of the present invention. For those skilled in the art, other drawings may be obtained according to these drawings without any creative work. In the drawings, the same reference numerals indicate the same parts. The drawings may not be drawn to scale, so as not to unnecessarily obscure the essential of the present invention.

FIG. 1 is a flowchart of a method for in situ cleaning of an MOCVD reaction chamber according to a first embodiment of the invention;

FIG. 2 is a schematic structural diagram of the MOCVD reaction chamber according to the embodiments of the invention;

FIG. 3 is a flowchart of a method for in situ cleaning of an MOCVD reaction chamber according to a second embodiment of the invention; and

FIG. 4 is a flowchart of a method for in situ cleaning of an MOCVD reaction chamber according to a third embodiment of the invention.

### DETAILED DESCRIPTION OF THE INVENTION

To make the object, technical solutions and advantages of the invention clearer, in the following, the technical solutions in embodiments of the present invention are described clearly and completely in conjunction with the drawings. It is obvious that the described embodiments are only some of the embodiments of the present invention. Other embodiments obtained by those skilled in the art on the basis of the embodiments of the present invention without creative work fall into the scope of protection of the present invention.

In order to solve the problem in the prior art that deposits on surfaces with a relatively low temperature inside an MOCVD reaction chamber can not be removed effectively, a method for in situ cleaning of an MOCVD reaction chamber is proposed by the inventors after research, which will be described in detail in the following.

### First Embodiment

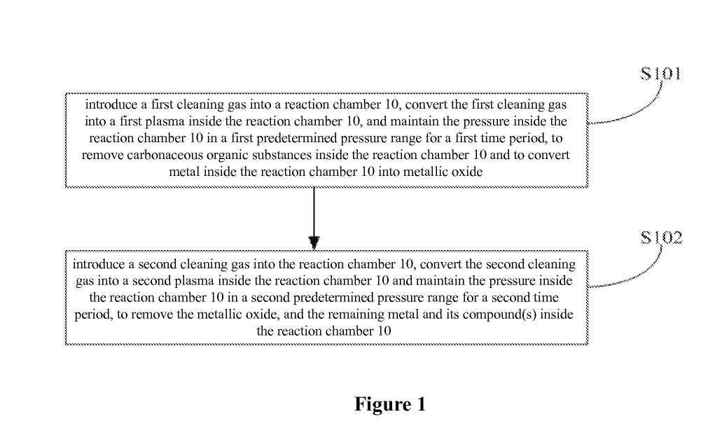

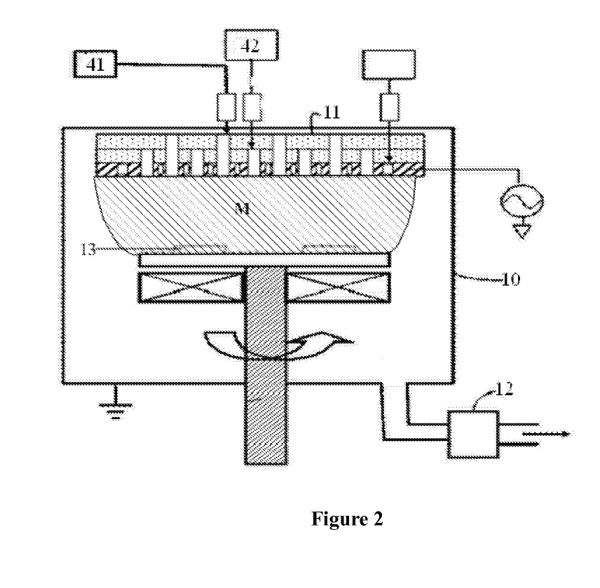

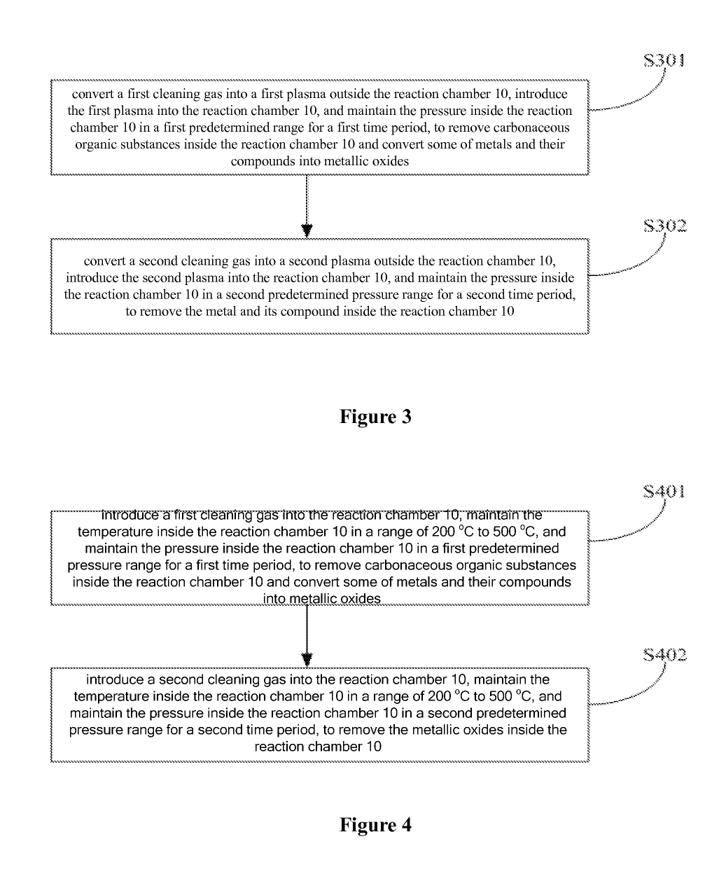

FIG. 1 shows a flowchart of a method for in situ cleaning of an MOCVD reaction chamber according to the first embodiment of the invention. In the following, the method will be explained in detail in conjunction with a schematic structural diagram (i.e., FIG. 2) of the MOCVD reaction chamber.

Step S101: introducing a first cleaning gas into a reaction chamber 10, and converting the first cleaning gas into first plasma inside the reaction chamber 10, and maintaining the pressure inside the reaction chamber 10 in a first predetermined pressure range for a first time period, to remove carbonaceous organic substances inside the reaction chamber 10 and to convert metal(s) inside the reaction chamber 10 into metallic oxide(s).

Specifically, the first cleaning gas in the first embodiment of the present invention may include a first oxygen-containing gas which may be one of O₂, O₃, CO₂, H₂O₂, N₂O or any combination thereof. Preferably, the first oxygen-containing gas in the embodiment of the present invention includes gas having strong oxidizability, such as O₃ and H₂O₂.

If the first cleaning gas only includes one type of gas, the gas may be introduced into the reaction chamber 10 through one intake duct (such as intake duct 41 or 42); and if the first cleaning gas includes multiple types of gases, the multiple types of gases may be introduced into the reaction chamber 10 through multiple intake ducts, to ensure that these gases are introduced into the reaction chamber 10 separately, that is, these gases are not mixed until they enter into the reaction chamber 10. Moreover, if the first cleaning gas includes multiple types of gases, these gases may also be mixed before being introduced into the reaction chamber 10, and then the mixed gas is introduced into the reaction chamber 10 through the intake duct 41 or 42.

In Step S101, the first cleaning gas is converted into the plasma after entering into the reaction chamber 10. Specifically, an RF (radio frequency) voltage with a certain power may be applied between a shower head 11 and a susceptor 13 inside the reaction chamber 10, and the first cleaning gas is converted into the first plasma by the RF voltage in a reaction region M inside the reaction chamber 10 (for example, the reaction region may be a region between the shower head 11 and the susceptor 13, where the susceptor 13 is used to place substrates to be processed for preparing a compound of Group III element(s) and Group V element(s)). Moreover, the first cleaning gas may also be converted into the first plasma in a region inside the reaction chamber 10 other than the reaction region M. Specifically, the RF voltage with a certain power may be applied between an inner wall of the reaction chamber 10 and the susceptor 13, or the RF voltage with a certain power may be applied between the inner wall of the reaction chamber 10 and the shower head 11. The first cleaning gas is converted into the first plasma by the RF voltage in the region other than the reaction region M (the region inside the reaction chamber 10 other than the reaction region M in FIG. 2). Certainly, in the first embodiment of the invention, the way to convert the first cleaning gas into the plasma is not limited to such two ways, and other common ways in the art may also be used, and it will not be repeated herein.

After the first cleaning gas is converted into the first plasma inside the reaction chamber 10, the pressure inside the reaction chamber is maintained in a first predetermined pressure range (for example, 0.1 Torr to 10 Torr) for a first time period (for example, longer than 5 minutes), so that the first cleaning step (i.e. the step of removing the carbonaceous organic substances inside the reaction chamber) is carried out adequately. For example, the pressure inside the reaction chamber may be maintained in a range of 0.1 Torr to 10 Torr for 5 minutes to 30 minutes. Those skilled in the art may properly select the pressure inside the reaction chamber and the reaction time as required in the practical cleaning, which would not be listed herein.

During the cleaning, the gas exhausting device 12 may be kept in an open state, so that, in one aspect, the gaseous product generated after the first plasma reacts with the deposits inside the reaction chamber 10 may be discharged continuously from the reaction chamber to speed up the course of cleaning and to improve the cleaning effect, and in another aspect, the pressure inside the reaction chamber 10 may also be maintained at a certain level to meet the requirement during the cleaning That is, in the first embodiment, the pressure inside the reaction chamber 10 may also be controlled by controlling the degree of opening of the gas exhausting device 12. That is to say, the pressure inside the reaction chamber 10 may be controlled by controlling the gas displacement of the gas exhausting device 12.

In this step, the first oxygen-containing gas (O₂, H₂O₂ or the like) is mainly utilized to convert the carbonaceous organic substances in the deposits inside the reaction chamber into gaseous carbon-oxygen compounds due to the oxidizability of the first oxygen-containing gas, and the gaseous carbon-oxygen compounds are discharged from the reaction chamber 10 through the gas exhausting device 12, so the organic substances inside the reaction chamber 10 are removed. In addition, the oxygen-containing gas may also oxidize some of the metals and their compounds in the deposits inside the reaction chamber 10 into metallic oxides which are easier to be removed in subsequent steps.

In addition, the deposits inside the reaction chamber 10 generally are the mixture of the carbonaceous organic substances and metal and its compound(s). In the case where the deposits are thick, the carbonaceous organic substances at the bottom layer of the deposits are covered by the metal and its compound(s) at the upper layer of the deposits, and therefore it may be not possible to completely convert the carbonaceous organic substances in the deposits into the gaseous carbonaceous compounds by only using the first cleaning gas with oxidizability. Therefore, for the purpose that the carbonaceous organic substances in the deposits react adequately, in this step, the first cleaning gas may further include a certain amount of second halogen-containing gas. In this case, the metal and its compound(s) above the carbonaceous organic substances are prone to react with the second halogen-containing gas to generate gaseous metal halide(s) which may be discharged from the reaction chamber 10 by the gas exhausting device 12. For example, the metal and its compound(s) such as GaN, InN or AlN usually remain inside the MOCVD reaction chamber. The plasma of the second halogen-containing gas (such as Cl₂) inside the reaction chamber 10 may react with the metal and its compound(s) such as GaN, InN and AlN to generate gaseous GaCl₃, InCl, AlCl₃ and so on.

The main object of Step S101 is to remove the carbonaceous organic substances inside the reaction chamber. Therefore, in this step, in the first cleaning gas, the mole fraction of the oxygen-containing gas may be larger than the mole fraction of the second halogen-containing gas, and the second halogen-containing gas may include one of HCl, BCl₃, Cl₂, a gas mixture of H₂/Cl₂ (in this application, the term “gas mixture of H₂/Cl₂” represents “the gas mixture of H₂ and Cl₂”, and other similar terms represent similar meaning), HBr or any combination thereof. Of course, this is only one preferable embodiment, and in practice, in the first cleaning gas, the proportion between the mole fraction of the oxygen-containing gas and the mole fraction of the second halogen-containing gas may not be limited thereto.

Moreover, in order to improve the cleaning effect and the speed of cleaning, in this step, the first cleaning gas may further include a certain amount of Ar. Ar may be converted into the plasma of Ar inside the reaction chamber 10. The plasma of Ar is capable of speeding up the cleaning reaction (including the reaction of the reducing gas with the carbonaceous organic substances and/or the reaction of the halogen-containing gas with the metal and its compound(s)).

Under the condition of appropriate temperature, appropriate pressure and the like, the plasma converted from the first cleaning gas may break the carbon bond of the carbonaceous organic substances or carbonaceous polymers and react with the carbonaceous organic substances or carbonaceous polymers to generate the gaseous carbonaceous compounds. Thus, the relatively stable organic ligands and polymers inside the reaction chamber are converted into highly active substances which may be easily removed. The thus obtained substances may be drawn away from the reaction chamber along with a gas flow by a pump under the particular condition of gas flow, pressure, temperature and so on, thereby achieving the purpose of cleaning.

It should be noted that, in the first embodiment of the present invention, any one or both of the following Steps S101-A1 and S101-A2 may be performed in place of Step S101.

Step S101-A1: converting the first cleaning gas into the first plasma outside the reaction chamber 10, and introducing the first plasma into the reaction chamber 10;

Step S101-A2: introducing the first cleaning gas into the reaction chamber 10, and maintaining the temperature inside the reaction chamber 10 in a range of 200° C. to 500° C.

The first cleaning gas in Step S101-A1 and Step S101-A2 may have the same meaning as the first cleaning gas in Step S101. Here the expressing of “have the same meaning” means that the first cleaning gas herein has a same range as the first cleaning gas in Step S101 (for example, both include the first oxygen-containing gas). However, any different kind of gas in this range may be selected. The expressing of “have the same meaning” in the following is in the same case.

Moreover, Step S101-A1 and Step S101-A2 may be carried out while Step S101 is being carried out, to further speed up the cleaning reaction.

Step S102: introducing a second cleaning gas into the reaction chamber 10, and converting the second cleaning gas into second plasma inside the reaction chamber 10, and maintaining the pressure inside the reaction chamber 10 in a second predetermined pressure range for a second time period, to remove the metal and its compound(s) inside the reaction chamber 10.

In the first embodiment of the invention, the second cleaning gas may include a first halogen-containing gas which may be one of HCl, BCl₃, Cl₂, a mixture of H₂/Cl₂ gas, HBr or any combination thereof.

Specifically, the second cleaning gas may be introduced into the reaction chamber 10 through the intake duct 41 or 42. After Step S101, the carbonaceous organic substances inside the reaction chamber 10 are substantially removed, and the remainder is mainly metal (such as Ga, Al and In) and its compound(s). Therefore, in this step, the second cleaning gas including the halogen-containing gas is introduced into the reaction chamber 10. The second cleaning gas may be converted into the plasma in the reaction region M or the region inside the reaction chamber 10 other than the reaction region M under the action of the RF voltage (referring to the description in Step S101). The plasma is capable of adequately reacting with the metal and its compound(s) remained in the deposits to generate the gaseous metal halide, and then the gaseous metal halide is discharged from the reaction chamber 10 by the gas exhausting device 12.

After the second cleaning gas is converted into the plasma inside the reaction chamber 10, the pressure inside the reaction chamber is maintained in a second predetermined pressure range (for example, 0.1 Torr to 10 Torr) for a second time period (for example, longer than 3 minutes), so that the second cleaning step (i.e. the step of removing the metal and its compound(s)) is adequately carried out to completely remove the metal and its compound(s) remained inside the reaction chamber. For example, the pressure inside the reaction chamber may be maintained in a range of 0.1 Torr to 10 Torr for 5 minutes to 30 minutes. Those skilled in the art may properly select the pressure inside the reaction chamber and the reaction time as required in the practical cleaning, which would not be listed herein. Furthermore, a few of metallic oxides generated in Step S101 also may be removed in this step.

Specifically, the pressure inside the reaction chamber 10 may be controlled by controlling the flow rate of the second cleaning gas introduced into the reaction chamber 10. Alternatively, the pressure inside the reaction chamber 10 may be controlled by controlling the degree of opening of the gas exhausting device 12.

In this step, the halogen which is converted into the plasma reacts with the metal and its compound(s) remained inside the reaction chamber and the metallic oxide(s) generated in step S101, to convert the remained metal and its compound(s) and the metallic oxide(s) into the gaseous metal halide(s) and discharge the gaseous metal halide(s) from the reaction chamber 10. For example, the metal and its compound(s) such as Ga, In, Al, GaN, InN and AlN are usually prone to remain inside the MOCVD reaction chamber. The plasma of the second halogen-containing gas (such as Cl₂) inside the reaction chamber 10 may react with the metal and its compound(s) such as Ga, In, Al, GaN, InN and AlN to generate gaseous GaCl₃, InCl, AlCl₃ and so on.

Moreover, in Step S102, the second cleaning gas may also include a certain amount of oxygen-containing gas (such as O₂). The oxygen-containing gas may be converted into plasma inside the reaction chamber 10, and then react with the carbonaceous organic substances which may be remained inside the reaction chamber 10, to completely remove the carbonaceous organic substances in the deposits, and to further improve the cleaning effect.

The main object of Step S102 is to remove the metal and its compound(s) and a few of metallic oxides inside the reaction chamber. Therefore, in this step, in the second cleaning gas, the mole fraction of the first halogen-containing gas may be larger than the mole fraction of the second oxygen-containing gas. Of course, this is only a preferable embodiment, and in practice, in the second cleaning gas, the proportion between the mole fraction of the first halogen-containing gas and the mole fraction of the second oxygen-containing gas may not be limited thereto.

Furthermore, in order to further improve the cleaning effect and the speed of cleaning, in this step, the second cleaning gas may further include a proper amount of Ar. Ar may be converted into the plasma of Ar inside the reaction chamber 10. The plasma of Ar is capable of speeding up the cleaning reaction.

It should be noted that, in the first embodiment of the invention, any one or both of the following Step S102-B1 and Step S102-B2 may be carried out in place of Step S102.

Step S102-B1: converting the second cleaning gas into the second plasma outside the reaction chamber 10, and introducing the second plasma into the reaction chamber 10;

Step S102-B2: introducing the second cleaning gas into the reaction chamber 10, and maintaining the temperature inside the reaction chamber 10 in a range of 200° C. to 500° C.

The second cleaning gas in Step S102-B1 and Step S102-B2 may have the same meaning as the second cleaning gas in Step S102.

Moreover, Step S102-B1 and Step S102-B2 may be carried out while Step S102 is being carried out, to further speed up the cleaning reaction.

In the method for in situ cleaning of the MOCVD reaction chamber provided in the first embodiment of the present invention, firstly, the first cleaning gas including the first oxygen-containing gas is introduced into the reaction chamber and converted into the plasma inside the reaction chamber, and the carbonaceous organic substances inside the reaction chamber are removed by utilizing the oxidizability of the first cleaning gas; then the second cleaning gas including the first halogen-containing gas is introduced into the reaction chamber and converted into the plasma inside the reaction chamber to remove the metal and its compound(s) and a few metallic oxides remained inside the reaction chamber, thereby the deposits inside the MOCVD reaction chamber are removed completely.

It should be noted that, in the first embodiment of the invention, Step S101 and Step S102 may be carried out in succession, that is, Step S102 is carried out immediately after Step S101 is completed. Alternatively, Step S101 and Step S102 may also be carried out intermittently, that is, Step S102 is carried out after a period of time since Step S101 is completed. Of course, during the period of time, the gas exhausting device 12 may always be kept in an exhausting state, so the gaseous product generated in Step S101 is completely discharged from the reaction chamber and the cleaning efficiency of Step S102 may further be improved.

It should be noted that, in the first embodiment of the invention, the duration for carrying out Step S101 and/or Step S102 may be properly extended, to completely remove the carbonaceous organic substances inside the reaction chamber by Step S101 and completely remove the metal and its compound(s) inside the reaction chamber by Step S102. Technician may monitor whether the carbonaceous organic substances and/or the metal and its compound(s) inside the reaction chamber are removed completely by using an assistant detection device. Since it is not the focus of this application, it will not be described in detail herein.

Moreover, in the embodiment of the invention, Step S101 and Step S102 may also be carried out repeatedly, to further improve the cleaning effect.

In the following, the technical solutions according to the first embodiment of the present invention are described in detail with two specific examples.

### FIRST EXAMPLE

A: O₂, Cl₂ and Ar are introduced into the reaction chamber 10 simultaneously, for example, through the intake ducts shown in FIG. 2 at the flow rate of 250 sccm, 250 sccm and 500 sccm, respectively. A RF voltage is applied between the shower head 11 and the inner wall of the reaction chamber 10 with a power maintained at 2000 W and an RF frequency of 13.56 MHz. The internal pressure of the reaction chamber 10 is kept to be 0.72 Torr, and the reaction time period of the plasma is 10 minutes (i.e., the predetermined time period is 10 minutes). After this step, most of the deposits inside the reaction chamber 10 are removed.

B: HCl and Ar are introduced into the reaction chamber 10 simultaneously at the flow rate of 500 sccm for each of HCl and Ar. An RF voltage is applied between the inner wall of the reaction chamber 10 and the shower head 11 with the RF power maintained to be 2000 W and the RF frequency of 13.56 MHz, the pressure inside the reaction chamber is maintained to be 0.68 Torr and the reaction time of the plasma lasts for 5 minutes (i.e. the second time period is 5 minutes). After this step, all of the deposits inside the reaction chamber may be removed.

### SECOND EXAMPLE

A: O₂, Cl₂ and Ar are introduced into the reaction chamber 10 simultaneously, for example, through the intake ducts shown in FIG. 2 at the flow rate of 250 sccm, 250 sccm and 500 sccm, respectively. An RF voltage is applied between the inner wall of the reaction chamber 10 and the shower head 11 with the RF power maintained to be 2000 W and the RF frequency maintained to be 13.56 MHz, the pressure inside the reaction chamber is maintained to be 0.72 Torr and the reaction time of the plasma lasts for 10 minutes. After this step, most of the carbonaceous organic substances in the deposits inside the reaction chamber are removed. In addition, in this step, the oxygen-containing gas may also react with some of metals and their compounds to generate metallic oxides.

B: H₂, Cl₂ and Ar are introduced into the reaction chamber 10 simultaneously at the flow rate of 250 sccm, 250 sccm and 500 sccm, respectively. An RF voltage is applied between the inner wall of the reaction chamber 10 and the shower head 11 with the RF power maintained to be 2000 W and the RF frequency maintained to be 13.56 MHz, and the pressure inside the reaction chamber is maintained to be 0.68 Torr and the reaction time of the plasma lasts for 5 minutes. After this step, most of the carbonaceous organic substances, the metals and their compounds and the metallic oxides in the deposits inside the reaction chamber 10 may be removed;

Since H₂ and Cl₂ are usually introduced into the MOCVD reaction chamber during the preparation of the compound of Group III element(s) and Group V element(s) in the MOCVD, in this step, a gas mixture of H₂ and Cl₂ is employed to remove the metal and its compound in the deposits, thus there is no need to add an extra gas into the reaction chamber 10. Therefore, not only the cleaning process but also the cleaning apparatus for the MOCVD reaction chamber may be simplified (i.e. no excessive intake duct needs to be added).

It should be noted that, in the embodiment of the invention, in the course of the in situ cleaning of the MOCVD reaction chamber (such as Step S101, Step S101-A1, Step S102 and Step S102-B1), the reaction chamber 10 may be heated to maintain the temperature inside the reaction chamber 10 at a certain level. In this way, not only the speed of in situ cleaning can be improved, but also it can be ensured that the by-product generated after the reaction of the plasma with the deposits is gaseous. Therefore, it is avoided that the by-product remains inside the reaction chamber when it meets the surfaces with a relatively low temperature and becomes liquid or solid. For example, the temperature inside the reaction chamber 10 may be maintained in a range of 70° C. to 100° C. (such as 70° C., 80° C. or 100° C.). Specifically, the temperature inside the reaction chamber may be maintained by heating the outer wall or the inner wall of the reaction chamber.

In the method for cleaning the MOCVD reaction chamber in the embodiment of the invention, the reducing plasma is used to react with the deposits to convert the deposits into the gaseous products, which are discharged from the reaction chamber by the gas exhausting device. In the case where the deposits inside the MOCVD reaction chamber (particularly the deposits on the surfaces with a relatively low temperature) are removed by using the in situ cleaning method according to the first embodiment of the present invention, the process may be stable, the performance may be improved and the whole MOCVD process may be performed automatically.

It should be noted that the method for in situ cleaning of the MOCVD reaction chamber according to the embodiments of the invention may also be implemented in other ways. For example, the plasma may be generated inside the reaction chamber. Alternatively, the plasma may be generated outside the reaction chamber and then be introduced into the reaction chamber.

### Second Embodiment

A method for in situ cleaning of an MOCVD reaction chamber according to the second embodiment of the invention is similar to the method according to the first embodiment of the invention. The difference lies in that, in the second embodiment of the invention, plasma may be generated outside the reaction chamber 10, and then the plasma may be introduced into the reaction chamber via an intake duct. For simplicity, only the difference of the second embodiment from the first embodiment of the invention is described here. For those skilled in the art, it is easy to obtain other contents about the second embodiment of the invention from the related description in the first embodiment of the invention, and it will not be repeated herein.

Step S301: converting a first cleaning gas into first plasma outside a reaction chamber 10, introducing the first plasma into the reaction chamber 10, and maintaining the pressure inside the reaction chamber 10 in a first predetermined pressure range for a first time period, to remove carbonaceous organic substances inside the reaction chamber 10 and to convert some of the metals and their compounds into metallic oxides.

The first cleaning gas in the second embodiment of the present invention may include a first oxygen-containing gas which may be one of O₂, O₃, CO₂, H₂O₂, N₂O or any combination thereof. Preferably, in the embodiments of the present invention, a gas having strong oxidizability, such as O₃ or H₂O₂, is selected as the first oxygen-containing gas.

Specifically, the first plasma may be generated by employing a plasma converting device. For example, the first oxygen-containing gas may be introduced into the plasma converting device firstly, and then the first oxygen-containing gas may be converted into the first plasma inside the plasma converting device. The first plasma may be introduced into the reaction chamber through a gas intake device connected to the reaction chamber.

After the first plasma is introduced into the reaction chamber, the pressure inside the reaction chamber is maintained in a first predetermined pressure range for a first time period. For example, the pressure inside the reaction chamber may be maintained in a range of 0.1 Torr to 10 Torr (as an example of the first predetermined pressure range) for more than 5 minutes (for example, 5 minutes to 30 minutes), so that the first plasma reacts with the carbonaceous organic substances in the deposits.

It should be noted that, in the second embodiment of the invention, any one or both of the following Step S301-A1 and Step S301-A2 may be carried out in place of Step S301.

Step S301-A1: introducing the first cleaning gas into the reaction chamber 10, and converting the first cleaning gas into the first plasma inside the reaction chamber 10;

Step S301-A2: introducing the first cleaning gas into the reaction chamber 10, and maintaining the temperature inside the reaction chamber 10 in a range of 200° C. to 500° C.

The first cleaning gas in Step S301-A1 and Step S301-A2 may have the same meaning as the first cleaning gas in Step S301.

Moreover, Step S301-A1 and Step S301-A2 may be carried out while Step S301 is being carried out, to further speed up the cleaning reaction.

Step S302: converting a second cleaning gas into second plasma outside the reaction chamber 10, and introducing the second plasma into the reaction chamber 10, and maintaining the pressure inside the reaction chamber 10 in a second predetermined pressure range for a second time period, to remove metal and its compound(s) inside the reaction chamber 10.

Specifically, the second plasma may be generated by using a plasma converting device. For example, the second cleaning gas may firstly be introduced into the plasma converting device and then may be converted into the second plasma inside the plasma converting device.

After the second plasma is introduced into the reaction chamber 10, the pressure inside the reaction chamber 10 may be maintained in a range of 0.1 Torr to 10 Torr (as an example of the second predetermined pressure range) for more than 3 minutes (for example, 5 minutes to 30 minutes), so that the second plasma adequately reacts with the metal and its compound(s) remained in the deposits to generate a gaseous metal halide and the gaseous metal halide is discharged from the reaction chamber by a gas exhausting device.

The first cleaning gas in the second embodiment of the invention has the same meaning as that in the first embodiment of the invention, and the second cleaning gas in the second embodiment of the invention has the same meaning as that in the first embodiment of the invention.

It should be noted that, the description of parameters (such as the pressure, the time and the temperature), composition and content of the gas and so on in the first embodiment of the invention is also applicable to the solution in the second embodiment of the invention, which will not be repeated herein for succinctness. However, for those skilled in the art, a specific implementation may be obtained by combining the solution in the second embodiment of the invention with the corresponding content in the first embodiment of the invention, which falls into the scope of protection of the invention.

In the second embodiment of the invention, the first cleaning gas is converted into the first plasma and the second cleaning gas is converted into the second plasma outside the reaction chamber 10. The first plasma is introduced into the reaction chamber 10 to completely remove the carbonaceous organic substances inside the reaction chamber 10 and the second plasma is introduced into the reaction chamber 10 to completely remove the metal and its compound(s) inside the reaction chamber.

It should be noted that, in the second embodiment of the invention, Step S301 and Step S302 may be carried out in succession, that is, Step S302 is carried out immediately after Step S301 is completed. Alternatively, Step S301 and Step S302 may be carried out intermittently, that is, Step S302 is carried out after a period of time since Step S301 is completed. Certainly, during the period of time, the gas exhausting device 12 may always be kept in an exhausting state, so the gaseous product generated in Step S301 is completely discharged from the reaction chamber and the cleaning efficiency of Step S302 may further be improved.

In the above-mentioned first and second embodiments, it is mainly described in detail that the plasma (the first and/or second plasma) is used to remove the deposits (the carbonaceous organic substances and/or the metal and its compound(s)) inside the reaction chamber. However, in practice, the deposits inside the reaction chamber may also be removed by the thermal reaction of the cleaning gas with the deposits, according to additional embodiments of the invention.

### Third Embodiment

The third embodiment of the invention provides a method for in situ cleaning of an MOCVD reaction chamber, which is similar to the method in the first embodiment of the invention. The difference lies in that, in the third embodiment of the invention, the deposits inside the reaction chamber is removed by the thermal reaction of the cleaning gas with the deposits. For simplicity, only the difference of the third embodiment from the first embodiment of the invention is described in the third embodiment of the invention. For those skilled in the art, it is easy to obtain other contents about the third embodiment of the invention from the related description in the first embodiment of the invention, which will not be repeated herein.

Step S401: introducing a first cleaning gas into a reaction chamber 10, and maintaining the temperature inside the reaction chamber 10 in a range of 200° C. to 500° C., and maintaining the pressure inside the reaction chamber 10 in a first predetermined pressure range for a first time period, to remove a carbonaceous organic substances inside the reaction chamber 10 and to convert some of metals and their compounds into metallic oxides.

In the third embodiment of the present invention, the first cleaning gas may include a first oxygen-containing gas which may be one of O₂, O₃, CO₂, H₂O₂, N₂O or any combination thereof. Preferably, in the embodiments of the present invention, a gas having strong oxidizability, such as O₃ or H₂O₂, is selected as the first oxygen-containing gas.

Specifically, the pressure inside the reaction chamber 10 may be maintained in a first predetermined pressure range (for example, 0.1 Torr to 10 Torr) by heating an inner wall and/or a susceptor 13 and/or a shower head 11 of the reaction chamber 10, and the temperature inside the reaction chamber 10 may be maintained in a range of 200° C. to 500° C. (such as 200° C., 300° C. or 500° C.), so the first plasma reacts with the carbonaceous organic substances in the deposits. By using the method, the carbonaceous organic substances in the deposits inside the reaction chamber 10 may be removed completely in only one step.

It should be noted that, in the third embodiment of the invention, any one or both of the following Step S401-A1 and Step S401-A2 may be carried out in place of Step S401.

Step S401-A1: introducing the first cleaning gas into the reaction chamber 10, and converting the first cleaning gas into first plasma inside the reaction chamber 10;

Step S401-A2: converting the first cleaning gas into the first plasma outside the reaction chamber 10, and introducing the first plasma into the reaction chamber 10.

The first cleaning gas in Step S401-A1 and Step S401-A2 may have the same meaning as the first cleaning gas in Step S401.

Moreover, Step S401-A1 and Step S401-A2 may be carried out while Step S401 is being carried out, to further speed up the cleaning reaction.

Step S402: introducing a second cleaning gas into the reaction chamber 10, maintaining the temperature inside the reaction chamber 10 in a range of 200° C. to 500° C., and maintaining the pressure inside the reaction chamber 10 in a second predetermined pressure range for a second time period, to remove the metallic oxides inside the reaction chamber 10.

After the second cleaning gas is introduced into the reaction chamber 10, the pressure inside the reaction chamber 10 may be maintained in a range of 0.1 Torr to 10 Torr (as an example of the second predetermined pressure range) for more than 3 minutes (for example, 5 minutes to 30 minutes), so that the second cleaning gas has a complete thermal reaction with the metal and its compound(s) remained in the deposits to generate a gaseous metal halide which is discharged from the reaction chamber by a gas exhausting device.

The first cleaning gas in the third embodiment of the invention has the same meaning as that in the first embodiment of the invention, and the second cleaning gas in the third embodiment of the invention has the same meaning as that in the first embodiment of the invention.

It should be noted that, in the third embodiment of the invention, Step S401 and Step S402 may be carried out in succession, that is, Step S402 is carried out immediately after Step S401 is completed. Alternatively, Step S401 and Step S402 may be carried out intermittently, that is, Step S402 is carried out after a period of time since Step S401 is completed. Certainly, during the period of time, the gas exhausting device 12 may always be kept in an exhausting state, so the gaseous product generated in Step S401 is completely discharged from the reaction chamber and the cleaning efficiency of Step S402 may further be improved.

It should be noted that, the description of parameters (such as the pressure, the time and the temperature), the composition and content of the gas and so on in the first embodiment and/or the second embodiment of the invention is also applicable to the solution in the third embodiment of the invention, which will not be repeated herein for succinctness. However, for those skilled in the art, a specific implementation may be obtained by combining the solution in the third embodiment of the invention with the corresponding content in the first embodiment and/or the second embodiment of the invention, which falls into the scope of protection of the invention.

Thus, in the embodiments of the invention, the deposits inside the reaction chamber may be removed by the thermal reaction of the cleaning gas with the deposits. Moreover, the deposits inside the reaction chamber may also be removed by firstly converting the cleaning gas into the plasma and then making the plasma react with the deposits. The plasma may be generated outside the reaction chamber, or may be generated inside the reaction chamber (may be generated in the reaction region inside the reaction chamber, or may be generated in the region inside the reaction chamber other than the reaction region). Furthermore, by using the solution in the above-mentioned embodiments of the invention, the carbonaceous organic substances and the metal and its compound(s) in the deposits inside the reaction chamber may be removed completely by only one step.

The forgoing descriptions are only the preferred embodiments of the present invention, and it should be noted that numerous improvements and modifications made to the present invention can be made by those skilled in the art without departing from the principle of the present invention, and those improvements and modifications shall fall into the scope of protection of the invention.

1. A method for in situ cleaning of a Metal-Organic Chemical Vapor Deposition reaction chamber, comprising:
performing Step a, comprising:
introducing a first cleaning gas into the reaction chamber, and converting the first cleaning gas into a first plasma inside the reaction chamber; and/or,
converting the first cleaning gas into the first plasma outside the reaction chamber and introducing the first plasma into the reaction chamber; and/or,
introducing the first cleaning gas into the reaction chamber and maintaining a temperature inside the reaction chamber in a range of 200° C. to 500° C.; and
maintaining a pressure inside the reaction chamber in a first predetermined pressure range for a first time period to completely remove a carbonaceous organic substance inside the reaction chamber and convert a metal and its compound inside the reaction chamber into a metallic oxide, wherein the first cleaning gas comprises a first oxygen-containing gas; and
performing Step b, comprising:
introducing a second cleaning gas into the reaction chamber, and converting the second cleaning gas into a second plasma inside the reaction chamber; and/or,
converting the second cleaning gas into the second plasma outside the reaction chamber and introducing the second plasma into the reaction chamber; and/or,
introducing the second cleaning gas into the reaction chamber and maintaining the temperature inside the reaction chamber in a range of 200° C. to 500° C.; and
maintaining the pressure inside the reaction chamber in a second predetermined pressure range for a second time period to completely remove the metallic oxide inside the reaction chamber, wherein the second cleaning gas comprises a first halogen-containing gas.

2. The method according to claim 1, wherein the first cleaning gas further comprises Ar; and/or, the second cleaning gas further comprises Ar.

3. The method according to claim 1, wherein the first cleaning gas further comprises a second halogen-containing gas, and the second halogen-containing gas comprises one of HCl, BCl₃, Cl₂, a gas mixture of H₂/Cl₂, HBr or any combination thereof.

4. The method according to claim 3, wherein, in the first cleaning gas, the mole fraction of the first oxygen-containing gas is larger than the mole fraction of the second halogen-containing gas.

5. The method according to claim 1, wherein the second cleaning gas further comprises a second oxygen-containing gas, and the second oxygen-containing gas comprises one of O₂, O₃, CO₂, H₂O₂, N₂O, CO or any combination thereof

6. The method according to claim 5, wherein, in the second cleaning gas, the mole fraction of the first halogen-containing gas is larger than the mole fraction of the second oxygen-containing gas.

7. The method according to claim 1, wherein the first oxygen-containing gas comprises one of O₂, O₃, CO₂, H₂O₂, N₂O or any combination thereof

8. The method according to claim 1, wherein the first halogen-containing gas comprises one of HCl, BCl₃, a gas mixture of BCl/O₂, a gas mixture of H₂/Cl₂, Cl₂, HBr or any combination thereof.

9. The method according to claim 1, wherein the first time period is longer than 5 minutes and the second time period is longer than 3 minutes.
